(19) United States
(12) Patent Application Publication
(10) Pub. No.: US 2015/0263147 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventor: Hideki SEKIGUCHI, Yokohama Kanagawa (JP)

(21) Appl. No.: 14/474,297

(22) Filed: Sep. 1, 2014

(30) Foreign Application Priority Data
Mar. 14, 2014 (JP) 2014-052565

(51) Int. Cl. H01L 29/739; H01L 29/10; H01L 29/06; H01L 29/66

(52) U.S. Cl. CPC H01L 29/7395; H01L 29/66333; H01L 29/1095; H01L 29/0619

(57) ABSTRACT

A semiconductor device includes a substrate having an inner portion and a peripheral portion around the inner region. A recess is formed in the peripheral region inwardly of the substrate edge and extending into the substrate surface. A diffusion region and a first insulation layer is formed in the recess. The diffusion region is formed intermediate of the first insulation layer and the inner region. A first conductor extends over a portion of the diffusion region and the first insulation layer. A second insulation layer is located over the recess, the first conductor, the diffusion layer and the first insulation layer, and a second conductor layer is disposed on the second insulation layer. The distance between first and second conductor layers where the first conductor layer extends over the diffusion layer is greater than the distance therebetween where the second conductor overlies the first insulation layer.

### CROSS-REFERENCE TO RELATED APPLICATION

This application is based upon and claims the benefit of priority from Japanese Patent Application No. 2014-052565, filed Mar. 14, 2014, the entire contents of which are incorporated herein by reference.

### FIELD

An embodiment described herein relates to a semiconductor device.

### BACKGROUND

In a high voltage semiconductor device such as an IGBT (Insulated Gate Bipolar Transistor), the element terminal region thereof may be configured as a field plate structure. There has been a demand that the withstand voltage of such a semiconductor device be increased.

### DESCRIPTION OF THE DRAWINGS

FIG. 1 is a schematic plan view of an example of a semiconductor device according to an embodiment.

FIG. 2 is a schematic cross-sectional view of the example of a semiconductor device of FIG. 1 at line A1-A2 of FIG. 1, according to the embodiment.

### DETAILED DESCRIPTION

According to an embodiment, there is provided a semiconductor device having increased withstand voltage properties.

In general, according to one embodiment, there is provided a semiconductor device including: a substrate; a first conductive layer; a diffusion layer; a first insulation layer; a second conductive layer; a second insulation layer; and a third insulation layer. The substrate has a main surface, includes an inner region where a semiconductor element is mounted and an outer region which is formed around the inner region when the outer region is projected on the main surface, and is of a first conductive type. The first conductive layer is formed on the outer region, and includes: a first outer conductive portion; and a first inner conductive portion which is formed between the first outer conductive portion and the inner region when the first inner conductive portion is projected on the main surface. The diffusion layer is formed on the outer region, is of a second conductive type, and includes: an outer diffusion portion; and an inner diffusion portion. The outer diffusion portion is formed between the inner region and the first outer conductive portion when the outer diffusion portion is projected on the main surface. The inner diffusion portion is formed between the inner region and the outer diffusion portion when the inner diffusion portion is projected on the main surface. The first insulation layer is formed between the first outer conductive portion and the outer region, and includes: an outer insulation portion; and an inner insulation portion. The inner insulation portion is formed between the outer insulation portion and the outer diffusion portion when the inner insulation portion is projected on the main surface. The second conductive layer is formed between the outer region and the first outer conductive portion, and includes: a second outer conductive portion; a second inner conductive portion; and an intermediate conductive portion. The second outer conductive portion is formed between the inner insulation portion and the first outer conductive portion. The second inner conductive portion is formed between the outer diffusion portion and the first inner conductive portion. The intermediate conductive portion is formed between the second outer conductive portion and the second inner conductive portion when the intermediate conductive portion is projected on the main surface. The second insulation layer is formed between the first conductive layer and the diffusion layer, and between the first conductive layer and the second conductive layer. At least a portion of the third insulation layer is formed between the intermediate conductive portion and the outer region. A first distance between the outer region and the second outer conductive portion along a first direction directed toward the first conductive layer from the outer region is longer than a second distance between the outer region and the second inner conductive portion along the first direction, and is longer than a third distance between the outer region and the intermediate conductive portion along the first direction.

Hereinafter, respective embodiments are explained by reference to drawings.

The drawings are schematic or conceptual views and hence, the relationship between thicknesses and widths of respective portions, the ratio of the sizes of the respective portions, and the like are not always equal to those of an actual semiconductor device. Further, even when identical portions are described in the drawings, sizes or ratios of sizes of the portions may differ in different drawing figures.

In this disclosure and the respective drawings, elements identical to previously described elements in previously discussed drawings are given the same symbols, and detailed explanation of identical element is omitted when appropriate.

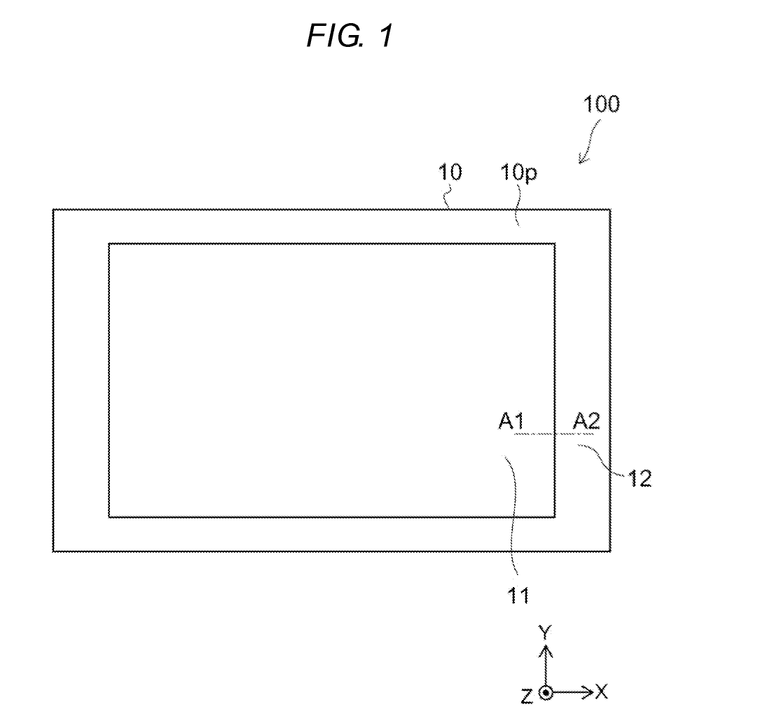

FIG. 1 is a schematic plan view of an example of a semiconductor device according to an embodiment.

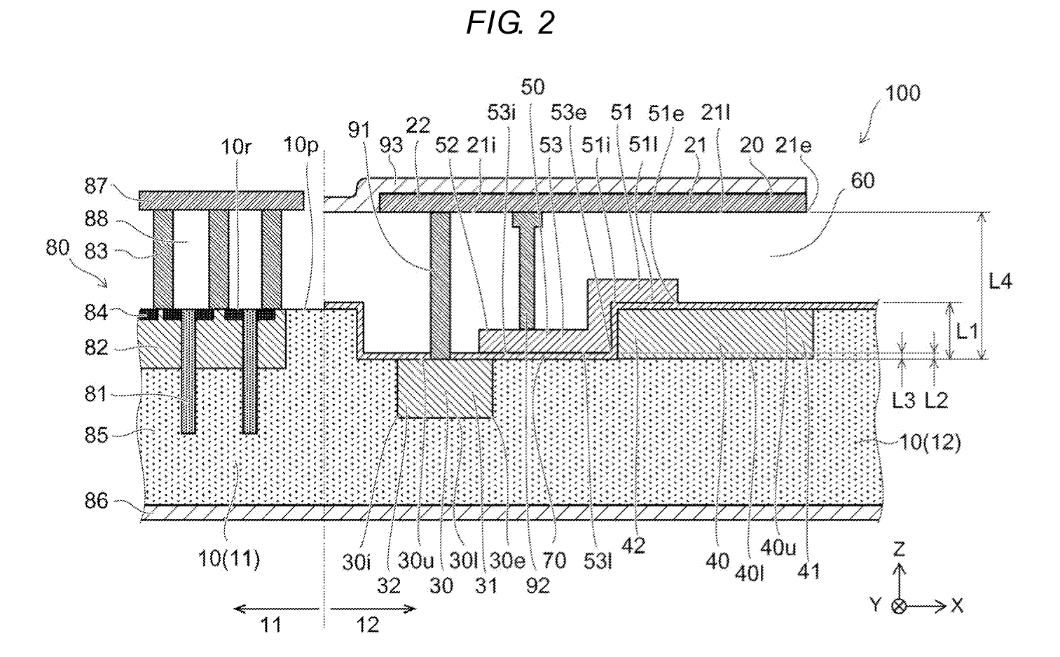

FIG. 2 is a schematic cross-sectional view of the example of a semiconductor device of FIG. 1 at line A1-A2 of FIG. 1.

As illustrated in FIG. 2, the semiconductor device 100 includes: a substrate 10; a first conductive layer 20; a diffusion layer 30; a first insulation layer 40; a second conductive layer 50; a second insulation layer 60; and a third insulation layer 70.

The substrate 10 has a main surface 10p. The substrate 10 includes an inner region 11 and an outer region 12 (FIGS. 1 and 2). The inner region 11 is an element region of the semiconductor device 100. The inner region 11 includes at least a portion of a semiconductor element 80. The outer region 12 is a terminal region of the semiconductor device 100. The outer region 12 is formed around the inner region 11 as shown in the plan view of FIG. 1.

The substrate 10 may be formed of silicon (Si), silicon carbide (SiC), gallium nitride (GaN) or the like, for example. The substrate 10 is of a first conductivity type. In this embodiment, the first conductivity type is an n-type.

The embodiment is explained hereinafter assuming a first conductivity type as an n-type and a second conductivity type as a p-type. The explanation made hereinafter is also applicable to a case where a first conductivity type is a p-type and a second conductivity type is an n-type.

The semiconductor element 80 includes, for example: a gate electrode 81; a body region 82; lines 83; diffusion regions 84 (source region); a drift region 85; a collector electrode 86; an emitter electrode 87; and an interlayer insulation layer 88.

The collector electrode 86 is arranged parallel to the emitter electrode 87 in the direction extending from the outer region 12 to the inner region 11. The body region 82 is formed between the collector electrode 86 and the emitter electrode 87 in the inner region 11. The body region 82 is formed on a front surface (main surface 10p) side of the substrate 10. The body region 82 is a region of the substrate of a second conductivity type, for example.

The drift region 85 is formed between the collector electrode 86 and the body region 82. The drift region 85 is a region of a first conductivity type, for example.

The interlayer insulation layer 88 is formed between the emitter electrode 87 and the body region 82. The interlayer insulation layer 88 may be formed using silicon oxide, for example.

A plurality of diffusion regions 84 are formed on a portion of an area between the body region 82 and the interlayer insulation layer 88. The plurality of diffusion regions 84 configure a source region.

A gate electrode 81 is formed between each two source regions 84 among the plurality of source regions 84, such that the two source regions are bounded by the body region 82 on the surfaces thereof not abutting the gate electrode. The gate electrode 81 extends from main surface 10p adjacent to the interlayer insulation layer 88, through body portion 82, and inwardly of the drift region 85. The gate electrode 81 extends along the direction extending between the collector electrode and the emitter electrode 87. The gate electrode 81 terminates within the drift region 85.

The plurality of lines 83 are formed to extend from diffusion regions 84 separated from one another by the body portion 82, i.e., from contact with two different diffusion regions disposed against different gate electrodes 81, and the emitter electrode 87. The plurality of lines 83 respectively electrically connect the diffusion regions 84 and the emitter electrode 87 to each other.

The semiconductor element 80 is an IGBT, for example. In this embodiment, the semiconductor element 80 may be also any one of a MOSFET, a diode and other high withstand voltage elements.

The first conductive layer 20 is formed over the outer region 12 of the substrate 10. The first conductive layer 20 includes a first outer conductive portion 21 and a first inner conductive portion 22. The first inner conductive portion 22 is formed between the first outer conductive portion 21 and the inner region 11 of the semiconductor device 100. The first conductive layer 20 is a field plate, for example.

The first conductive layer is formed using, for example, tungsten (W), copper (Cu), molybdenum (Mo), aluminum (Al), ruthenium (Ru) or the like.

In FIG. 2, the direction toward the first conductive layer 20 from the substrate 10 is the Z-axis direction (first direction). One direction perpendicular to the z-axis direction, in the Fig. in the direction from the inner region 11 to the outer region 12, is the X-axis direction. The direction perpendicular to the X-axis direction and also perpendicular to the Z-axis direction is the Y-axis direction.

The diffusion layer 30 is formed in the outer region 12. For example, the diffusion layer 30 is formed within the substrate 10 on a front surface side (main surface 10p side) of the substrate 10.

The diffusion layer 30 includes an outer diffusion portion 31 and an inner diffusion portion 32. The outer diffusion portion 31 is formed in the outer region adjacent to the inner region 11, and is embedded below, in the Z direction, the first inner conductive portion 22. The inner diffusion portion 32 is formed between the inner region 11 and the outer diffusion portion 31.

The diffusion layer 30 is of a second conductivity type. The diffusion layer 30 is a guard ring diffusion layer, for example. As described later, an electric field in the inner region 11 may be reduced by the presence of the guard ring diffusion layer. A depth (a length along the Z-axis direction) of the diffusion layer 30 is 1 to 2 micrometers (μm) inclusive, for example. The depth of the diffusion layer 30 is approximately 1.6 μm, for example.

The first insulation layer 40 is formed on the outer region 12 spaced from the first outer conductive portion 21 in the X direction of the outer region 12. The first insulation layer 40 includes an outer insulation portion 41 and an inner insulation portion 42. The inner insulation portion 42 is formed between the outer insulation portion 41 and the outer diffusion portion 31.

The first insulation layer 40 is formed of silicon oxide (SiO₂), for example. A thickness (a length along the Z-axis direction) of the first insulation layer 40 is 0.7 μm to 1.5 μm inclusive, for example. The thickness of the first insulation layer 40 is 1.15 μm, for example.

The second conductive layer 50 is formed extending over a portion of the first insulating layer 40, a portion of the outer portion 12 of the substrate 10, and a portion of the diffusion layer 30. The second conductive layer 50 includes a second outer conductive portion 51 which overlies the first insulator layer 40, a second inner conductive portion 52 which extends partially over the diffusion layer 30, and an intermediate conductive portion 53 extending between the second inner and second outer conductive portions 51, 52. The second conductive layer 50 is a field plate, for example.

The second conductive layer 50 is formed of polysilicon, for example. For example, a dopant is implanted into the polysilicon so that the polysilicon is conductive, i.e., doped polysilicon. The second conductive layer 50 may be formed using metal such as W, Cu, Mo, Al or Ru.

The second insulation layer 60 is formed between the first conductive layer 20 and the portion of the diffusion layer 30 not covered by the second conductive layer 50, the second conductive layer 50, and the outer insulation portion 41 which is not covered by the second conductive layer 50. At the outer region 12 of the substrate 10, the second insulation layer 60 is formed between the first outer conductive portion 21 of the first conductive layer 20 and the outer insulation portion 41 of the first insulating layer 40.

The second insulation layer 60 is formed of silicon oxide, for example. The second insulation layer 60 is formed as a film using a CVD (Chemical Vapor Deposition) method, for example. A thickness (a length along the Z-axis direction) of the second insulation layer 60 is 0.9 μm to 1.7 μm (both inclusive), for example. A distance between the outer insulation portion 41 of the first insulation layer 40 and the first outer conductive portion 21 along the Z-axis direction is 0.9 μm to 1.7 μm inclusive, for example. The thickness of the second insulation layer 60 is 1.35 μm, for example.

The third insulation layer 70 is formed directly on the upper, in the Z direction of FIG. 2, surface of the outer region 12 of the substrate, and it extends between the intermediate conductive portion 53, the second inner conductive portion 52 and the outer diffusion portion 31, and between the second outer conductive portion 51 and the inner insulation portion 42 in the outer region 12 of the substrate 10. The first connection portion 91 extends through the third insulator layer 70 to directly contact the first conductive layer 20. The third insulation layer 70 is formed using silicon oxide, for example.

In this embodiment, the semiconductor device 100 further includes: the first connection portion 91; a second connection portion 92; and a passivation film 93. The first connection portion 91 extends through the third insulator layer 70 and is formed to extend between the first conductive layer 20 and the diffusion layer 30 where it extends through the third insulator layer 70 to contact the diffusion layer 30. The first connection portion 91 thus electrically interconnects the first conductive layer 20 and the diffusion layer 30 to each other. The second connection portion 92 is formed between the first conductive layer 20 and the second conductive layer 50. The second connection portion 92 electrically interconnects the first conductive layer 20 and the second conductive layer 50 to each other.

Thus, the potential of the first conductive layer 20, a potential of the diffusion layer 30 and a potential of the second conductive layer 50 are maintainable at substantially the same potential. The first conductive layer 20 is also electrically connected to the emitter electrode 87. The first connection portion 91 and the second connection portion 92 are formed using W (tungsten) by chemical vapor deposition or physical vapor deposition (sputtering) processes, or the like, for example.

The passivation film 93 is formed on the first conductive layer 20 on the side thereof opposed to the second insulator layer 60. The passivation film 93 includes a silicon nitride layer, a silicon oxide layer and a polyimide layer sequentially formed, such that the silicon oxide layer is interposed between the silicon nitride layer and the polyimide layer, for example.

For discussion herein, a distance between the outer region 12 and the second outer conductive portion 51 along the Z-axis direction is a first distance L1, and a distance between the outer region 12 and the second inner conductive portion 52 along the Z-axis direction is a second distance L2.

Additionally, for discussion herein, a distance between the outer region 12 and the intermediate conductive portion 53 along the Z-axis direction is a third distance L3, and a distance between the outer region 12 and the first conductive layer 20 along the Z-axis direction is a fourth distance L4.

The first distance L1 is greater than the second distance L2 and is also greater than the third distance L3. The fourth distance L4 is greater than the first distance L1.

During operation of the semiconductor element 80, a voltage is applied to the collector electrode 86, for example. Due to the application of the voltage, a depletion layer spreads between the body region 82 and the drift region 85. When a high voltage is applied to the collector electrode 86, the depletion layer formed between the body region 82 and the drift region 85 spreads also in the lateral direction (the second direction directed toward the outer region 12 from the inner region 11, for example, the X-axis direction). For example, the depletion layer spreads to the periphery of the diffusion layer 30.

A pn junction is formed between the p-type diffusion layer 30 and the outer region 12 of the n-type substrate 10 thus forming the depletion layer. Accordingly, the depletion layer which spreads in the lateral direction when a high voltage is applied to the collector electrode 86 extends beyond the periphery of the diffusion layer 30 and further spreads in the lateral X direction in the outer region 12 of the substrate 10.

Outwardly of the diffusion layer 30, the intermediate conductive portion 53 faces the outer region 12 (substrate 10) via the third insulation layer 70. Accordingly, an electric field generated on the depletion layer in the lateral direction may be reduced.

Outwardly of the intermediate conductive portion 53, i.e., further in the X direction away from the inner region 11 of substrate 10, the second outer conductive portion 51 faces the outer region 12 (substrate 10) via the first insulation layer 40 and the third insulation layer 70. Accordingly, an electric field generated on the depletion layer in the lateral direction may be reduced.

Outwardly of the second outer conductive portion 51, i.e., yet further in the X direction away from the inner region 11 of substrate 10, the first outer conductive portion 21 faces the outer region 12 (substrate 10) via the first insulation layer 40, the second insulation layer 60 and the third insulation layer 70. Accordingly, an electric field generated on the depletion layer in the lateral direction may be reduced.

In this manner, in the semiconductor device 100 according to this embodiment, the diffusion layer 30, the intermediate conductive portion 53, the second outer conductive portion 51 and the first outer conductive portion 21 are sequentially arranged in the direction X extending from the inner region 11.

Further, the distance between the diffusion layer 30 and the outer region 12 (substrate 10), the distance between the intermediate conductive portion 53 and the outer region 12 (substrate 10), the distance between the second outer conductive portion 51 and the outer region 12 (substrate 10), and the distance between the first outer conductive portion 21 and the outer region 12 (substrate 10) along the Z-axis direction are increased as the distance thereof from the inner region 11 is increased. That is, the field plate terminal structure is a structure where an end of a field plate portion (the second conductive layer 50 and the first conductive layer 20) is located on the surface of the substrate in a stepwise manner. Accordingly, for example, a gradient of a potential in the X-axis direction in the outer region 12 may be controlled. For example, spreading of the depletion layer may be controlled and hence, an electric field generated on the substrate 10 may be reduced. Accordingly, the withstand voltage of the semiconductor device 100 is increased.

In this embodiment, an electric field in the outer region 12 is controlled by four elements of the device including the diffusion layer 30, the intermediate conductive portion 53, the second outer conductive portion 51 and the first outer conductive portion 21. For example, the electric field may be further reduced by increasing the number of elements which control such an electric field.

The diffusion layer 30 includes a first upper surface 30u on a first conductive layer 20 side and a first lower surface 30l on a side opposite to the first upper surface 30u. For example, the first lower surface 30l has a first outer lower end 30e positioned at an outer end of the diffusion layer 30, and a first inner lower end 30i positioned at an inner end of the diffusion layer 30. The first inner lower end 30i is formed between the first outer lower end 30e and the inner region 11.

The intermediate conductive portion 53 includes a second lower surface 53l which faces the outer region 12 in an opposed manner via the second insulation layer 70. For example, the second lower surface 53l has a second outer lower end 53e positioned at an outer end of the intermediate conductive portion 53, and a second inner lower end 53i positioned at an inner end of the intermediate conductive portion 53. The second inner lower end 53i is formed between the second outer lower end 53e and the inner region 11 when the second inner lower end 53i is projected on the main surface 10p.

The second outer conductive portion 51 has a third lower surface 51l which faces the inner insulation portion 42 in an opposed manner via the third insulation layer 70. For example, the third lower surface 51l has a third outer lower end 51e positioned at an outer end of the second outer conductive portion 51, and a third inner lower end 51i positioned at an inner end of the second outer conductive portion 51. The third inner lower end 51i is formed between the third outer lower end 51e and the inner region 11 when the third inner lower end 51i is projected on the main surface 10p.

The first outer conductive portion 21 has a fourth lower surface 21l which faces the first insulation layer 40 in an opposed manner thereto with the second insulation layer 60 and the third insulation layer 70 disposed therebetween. For example, the fourth lower surface 21l has a fourth outer lower end 21e positioned at an outer end of the first outer conductive portion 21, and a fourth inner lower end 21i positioned at an inner end (closer to inner region 11 of substrate 10) of the first outer conductive portion 21. The fourth inner lower end 21i is formed between the fourth outer lower end 21e and the inner region 11.

In the semiconductor device 100, for example, the first insulation layer 40, the second insulation layer 60 and the third insulation layer 70 are respectively formed using silicon oxide. In this case, the fourth outer lower end 21e, the third outer lower end 51e, the second outer lower end 53e, and the first outer lower end 30e are generally aligned along a line connecting the fourth outer lower end 21e and the first outer lower end 30e. By forming the diffusion layer 30, the intermediate conductive portion 53, the second outer conductive portion 51 and the first outer conductive portion 21 at such positions, a gradient of a potential in the outer region 12 (substrate 10) may be easily controlled. A depletion layer may be spread in the lateral direction and hence, an electric field in the outer region 12 may be reduced.

In the embodiment, an angle made by a straight line which connects the first outer lower end 30e of the diffusion layer 30 to the second outer lower end 53e of the second conductive layer 50 is at a first angle θ1 with respect to the X-Y plane.

Likewise, in the embodiment an angle made by a straight line which connects the first outer lower end 30e of the diffusion layer 30 and the third outer lower end 51e of the second conductor to each other is a second angle θ2 with respect to the X-Y plane.

Additionally, in the embodiment an angle between a straight line which connects the first outer lower end 30e and the fourth outer lower end 21e to each other and the X-Y plane is a third angle θ3, for example.

It is desirable that the first angle θ1 be 0.9 to 1.1 times (both inclusive) as large as the second angle θ2, for example. It is also desirable that the first angle θ1 is 0.9 to 1.1 times (both inclusive) as large as the third angle θ3, for example.

The main surface 10p of the substrate 10 has a first region 10r in which the semiconductor element 80 is located.

For example, the position of the first region 10r at the diffusion regions 84 closest to the transition of the inner region 11 to the outer region 12 of the substrate 10 is located to the inner region 11 side of, and along the Z-axis direction intermediate of, the position of the first conductive layer 20 along the Z-axis direction and the position of the first upper surface 30u along the Z-axis direction. In other words, the distance between the collector electrode 86 and the position 10r on the inner region 11 of the substrate 10 is intermediate in length of the distances between the collector electrode 86 and the first conductive layer 20 and the first upper surface 30u.

The first insulation layer 40 has a fifth lower surface 40l (lower surface) which faces the outer region 12 of substrate 10 and is spaced therefrom by intervening third insulator layer 70, and an upper surface 40u on a side opposite to the fifth lower surface 40l.

The position of the first region 10r (at the diffusion regions 84 closest to the transition of the inner region 11 to the outer region 12 of the substrate 10) is located to the inner region 11 side of, and along the Z-axis direction intermediate of, the position of the fifth lower surface 40l along the Z-axis direction and the position of the first conductive layer 20 along the Z-axis direction.

In this manner, for example, the diffusion layer 30 and the first insulation layer 40 are formed in recessed portions of the substrate 10 (outer region 12), or are formed into the substrate 10 in the outer region 12. For example, in manufacturing steps of the semiconductor device 100, the substrate 10 is etched away at the location corresponding to where the diffusion layer 30 and the first insulation layer 40 are formed. To form the diffusion layer 30, ions are injected into a portion of the substrate exposed to the etched region by ion implantation, or the like, thus forming the diffusion layer 30. A silicon oxide film, for example, is located in another portion of the etched region such as by blanket deposition of silicon oxide by a cvd method, followed by patterning and etching of the so formed silicon oxide to leave the first insulation layer 40 formed at the portion of the etched region furthest from the inner region 11 of substrate 10.

Thereafter, and after forming the third insulation layer 70 as a thin film, a film made of polysilicon or the like which forms the second conductive layer 50 is deposited over the insulation layer 70 in the outer region 12, and the resulting polysilicon film is patterned. Accordingly, the second conductive layer 50 having intermediate conductive portion 53 located over the outer portion 12 of substrate 11 with the third insulator layer 70 intervening therebetween, and the second outer conductive portion 51 located over the outer portion 12 of substrate 11 with the third insulator layer 70 and the first insulating layer intervening therebetween. This results in a “stepped” structure. As described previously, for example, by increasing portions of the outer region 12 where an electric field is controlled, the electric field of the device may be easily controlled. In this embodiment, the intermediate conductive portion 53 and the second outer conductive portion 51 may be simultaneously formed and hence, manufacturing efficiency of the semiconductor device 100 may be increased.

For example, the distance between the diffusion layer 30 and the first conductive layer 20 along the Z-axis direction is increased. Due to such a configuration, the distance between the diffusion layer 30 and the collector electrode 86, the distance between the intermediate conductive portion 53 and the collector electrode 86, the distance between the second outer conductive portion 51 and the collector electrode 86 and the distance between the first outer conductive portion 21 and the collector electrode 86 may be easily set such that these distances are increased toward the edge of the substrate 10. In this embodiment, the diffusion layer 30 and the intermediate conductive portion 53 are formed at etched portions of the substrate 10 and hence, the distance between the diffusion layer 30 and the first conductive layer 20 may be easily ensured. Due to such a configuration, for example, a thickness (a length along the Z-axis direction) of the second insulation layer 60 may be decreased. That is, a length between the first insulation layer 40 and the first conductive layer 20 along the Z-axis direction may be decreased.

For example, when the substrate 10 is not recessed at the location of the diffusion layer 30 and first insulation layer 40, there may be a case where a thickness of the second insulation layer 60 is large so as to ensure the desired distance between the diffusion layer 30 and the first conductive layer 20. Alternatively, when the substrate 10 is not recessed, there may be a case where another insulation layer is formed between the second insulation layer 60 and the first conductive layer 20 so as to ensure the distance between the diffusion layer 30 and the first conductive layer 20. When the thickness of the insulation layer is large in this manner, there may be a case where a whole wafer is warped due to a stress generated in the insulation layer, for example. Due to such warping, manufacturing yield is lowered. Accordingly, there may be a case where a facility used in the succeeding manufacturing step (a photolithography step, for example) is limited, because the warpage of the substrate limits the ability to focus a mask pattern onto a resist layer on the substrate 10.

To the contrary, in this embodiment, the diffusion layer 30 and the intermediate conductive portion 53 are formed at an etched and thus recessed portion of the substrate 10. Due to such a configuration, for example, a thickness of the second insulation layer 60 may be small. Accordingly, a semiconductor device having a high withstand voltage may be efficiently manufactured.

According to the embodiment, it is possible to provide a semiconductor device which may increase a withstand voltage thereof.

In the disclosure, “perpendicular” means not only “perpendicular” in a strict meaning of the term but also “perpendicular having a fluctuation which is caused in a manufacturing step or the like”, for example. That is, it is sufficient that “perpendicular” is “substantially perpendicular”.

The embodiments of the present disclosure have been explained by reference to the specific examples heretofore. However, the embodiments of the present disclosure are not limited to these specific examples. For example, with respect to the specific configurations of the respective elements such as the substrate, the first conductive layer, the diffusion layer, the second conductive layer and the first to third insulation layers, these configurations fall within the scope of the present disclosure provided that those who are skilled in the art may carry out the present disclosure in the same manner as these embodiments by suitably selecting the configurations from a known range and may acquire the substantially equal advantageous effects as these embodiments.

Further, the combination of two or more elements in each specific example within a technically possible range also falls within the scope of the present disclosure provided that the combination includes the gist of the present disclosure.

Further, all semiconductor devices which those who are skilled in the art may carry out by suitably changing designs based on the semiconductor devices described above as the embodiments of the present disclosure also fall within the scope of the present disclosure provided that these semiconductor devices include the gist of the present disclosure.

Still further, various variations and modifications are conceivable to those who are skilled in the art within a category of the technical concept of the present disclosure, and it is construed that these variations and modifications also fall within the scope of the present disclosure.

While certain embodiments have been described, these embodiments have been presented by way of examples only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate of a first conductivity type having a main surface and including an inner region where a semiconductor element is located and an outer region extending around the inner region;
a first conductive layer formed on the outer region, the first conductive layer comprising:
a first outer conductive portion; and
a first inner conductive portion extending between the first outer conductive portion and the inner region;
a diffusion layer of a second conductive type formed on the outer region, the diffusion layer comprising:
an outer diffusion portion formed between the inner region and the first outer conductive portion; and
an inner diffusion portion formed between the inner region and the outer diffusion portion;
a first insulation layer formed between the first outer conductive portion and the outer region, the first insulation layer comprising:
an outer insulation portion; and
an inner insulation portion formed between the outer insulation portion and the outer diffusion portion;
a second conductive layer formed between the outer region and the first outer conductive portion, the second conductive layer comprising:
a second outer conductive portion formed between the inner insulation portion and the first outer conductive portion;
a second inner conductive portion formed between the outer diffusion portion and the first inner conductive portion; and
an intermediate conductive portion formed between the second outer conductive portion and the second inner conductive portion;
a second insulation layer formed between the first conductive layer and the diffusion layer, and between the first conductive layer and the second conductive layer; and
a third insulation layer having at least a portion thereof formed between the intermediate conductive portion and the outer region, wherein
a first distance between the interface of the first insulation layer and the outer region of the substrate and the second outer conductive portion is longer than a second distance between the outer region of the substrate and the second inner conductive portion, and is also longer than a third distance between the outer region of the substrate and the intermediate conductive portion.

2. The semiconductor device according to claim 1, further comprising:
a first connection portion that electrically connects the first conductive layer and the diffusion layer to each other; and
a second connection portion that electrically connects the first conductive layer and the second conductive layer to each other.

3. The semiconductor device according to claim 1, wherein
the main surface includes a first region where the semiconductor element is located,
the diffusion layer has a first upper surface facing in the direction of the first conductive layer, and
a position of the first region along a first direction extending from the outer region of the substrate to the first conductive layer is located between a position of the first conductive layer and a position of the first upper surface.

4. The semiconductor device according to claim 3, wherein
the first insulation layer has a lower surface which faces the outer region in an opposed manner, and
the position of the first region along the first direction is located between the position of the first conductive layer and a position of the lower surface of the first insulation layer.

5. The semiconductor device according to claim 4, wherein
the diffusion layer has a first lower surface on a side opposite to the first upper surface,
the intermediate conductive portion has a second lower surface which faces the outer region in an opposed manner,
the second outer conductive portion has a third lower surface which faces the outer region in an opposed manner,
the first lower surface has a first outer lower end positioned at an outer end of the diffusion layer,
the second lower surface has a second outer lower end positioned at an outer end of the intermediate conductive portion,
the third lower surface has a third outer lower end positioned at an outer end of the second outer conductive portion, and
a first angle formed by a straight line which connects the first outer lower end and the second outer lower end to each other and a plane perpendicular to the first direction is 0.9 to 1.1 times (both inclusive) as large as a second angle formed by a straight line which connects the first outer lower end and the third outer lower end to each other and the plane.

6. The semiconductor device according to claim 5, wherein
the first outer conductive portion has a fourth lower surface which faces the first insulation layer in an opposed manner,
the fourth lower surface has a fourth outer lower end positioned at an outer end of the first outer conductive portion, and
the first angle is 0.9 to 1.1 times (both inclusive) as large as a third angle formed by a straight line which connects the first outer lower end and the fourth outer lower end to each other and the plane.

7. The semiconductor device according to claim 1, wherein the first insulation layer contains silicon oxide.

8. The semiconductor device according to claim 1, wherein the second insulation layer contains silicon oxide.

9. The semiconductor device according to claim 1, wherein a distance between the first insulation layer and the first outer conductive portion along the first direction is 0.9 to 1.7 micrometers (both inclusive).

10. The semiconductor device according to claim 1, wherein the thickness of the first insulation layer is 0.7 to 1.5 micrometers (both inclusive).

11. A semiconductor device, comprising:
a substrate of a first conductivity type having a semiconductor element formed at an inner portion thereof and an outer peripheral portion surrounding the inner portion and extending from the inner portion to the edge of the substrate;
a recess extending inwardly of the outer portion inwardly of the edge of the substrate; a diffusion region of a second conductivity type extending inwardly on the substrate at a location within the recess;
a first insulation layer disposed in the recess and located intermediate of the edge of the substrate and the diffusion region; and
a first conductor layer extending from a position overlying the diffusion region to a position overlying the first insulation layer.

12. The semiconductor device of claim 11, further comprising a second conductive layer overlying, and spaced from the recess.

13. The semiconductor device of claim 12, further comprising a second insulating layer disposed between the second conductive region and the recess.

14. The semiconductor device of claim 12, wherein the distance from the portion of the first conductive layer overlying the diffusion region to the second conductive layer is greater than the distance from the portion of the first conductive layer overlying the first insulation layer to the second conductive layer.

15. The semiconductor device of claim 11, further comprising a first conductive contact extending between the second conductive layer and the diffusion region and a second conductive contact extending between the second conductive layer and the first conductive layer at a location of the first conductive layer intermediate of the diffusion region and the first insulation layer.

16. The semiconductor device of claim 11, wherein the semiconductor element extends inwardly of the semiconductor substrate surface in the inner portion, and the surface of the substrate at the inner region extends above the surface of the substrate in the recess.

17. The semiconductor device of claim 16, wherein the semiconductor element is an IGBT.

18. A method of manufacturing a semiconductor device, comprising:
providing a substrate;
forming one or more semiconductor elements on an interior portion of the substrate surrounded by a peripheral region;
forming a recess inwardly of the substrate in the peripheral region;
forming a diffusion layer into the surface of the substrate within the recess;
forming a first insulation layer on the surface of the substrate within the recess, such that the first insulation layer has an upper surface coextensive with the non-recessed upper surface of the substrate in the peripheral region, wherein the diffusion layer is spaced from, and located to the inner region side of, the first insulation layer; and
forming a first conductor in the peripheral region, the first conductor overlying at least apportion of the diffusion region, at least a portion of the first insulation layer, and the surface of the substrate within the recess between the first insulation layer and the diffusion layer.

19. The method of claim 18, further comprising:
forming a second insulation layer over the inner region and the peripheral region, and
forming a second conductor layer over the second insulation layer.

20. The method of claim 18, further comprising electrically connecting the second conductor layer, through the second insulation layer, to the diffusion region and to the first conductor.
